(19) United States
(12) Patent Application Publication
(10) Pub. No.: US 2007/0082507 A1
(43) Pub. Date: Apr. 12, 2007

(54) Method and apparatus for the low temperature deposition of doped silicon nitride films

(75) Inventors: R. Suryanarayanan Iyer, St. Paul, MN (US); Jacob W. Smith, Santa Clara, CA (US); Sean M. Seutter, San Jose, CA (US); Kangzhan Zhang, Fremont, CA (US); Alexander Tam, Union City, CA (US); Kevin L. Cunningham, Mountain View, CA (US); Phani Ramachandran, Santa Clara, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/245,373

(22) Filed: Oct. 6, 2005

(51) Int. Cl. H01L 21/00

(52) U.S. Cl. 438/795; 257/E21.293

(57) ABSTRACT

A method and apparatus for low temperature deposition of doped silicon nitride films is disclosed. The improvements include a mechanical design for a CVD chamber that provides uniform heat distribution for low temperature processing and uniform distribution of process chemicals, and methods for depositing at least one layer comprising silicon and nitrogen on a substrate by heating a substrate, flowing a silicon containing precursor into a processing chamber having a mixing region defined by an adaptor ring and one or more blocker plates and an exhaust system heating the adapter ring and a portion of the exhaust system, flowing one or more of a hydrogen, germanium, boron, or carbon containing precursor into the processing chamber, and optionally flowing a nitrogen containing precursor into the processing chamber.

### BACKGROUND OF THE INVENTION

1. Field of the Invention

Embodiments of the invention generally relate to substrate processing. More particularly, embodiments of the invention relate to chemical vapor deposition chambers and processes.

2. Description of the Related Art

Chemical vapor deposited (CVD) films are used to form layers of materials within integrated circuits. CVD films are used as insulators, diffusion sources, diffusion and implantation masks, spacers, and final passivation layers, among other uses. The films are often deposited in chambers with specific heat and mass transfer characteristics to optimize the deposition of a physically and chemically uniform film across the surface of a substrate such as a silicon wafer, glass panel, etc.

Chemicals for depositing CVD films may be selected for their ability to react quickly at low temperature and provide films with more uniform crystalline structure, low dielectric constant (k), and improved stress profile. Low dielectric constant films are desirable for many applications, such as complementary metal oxide semiconductor (CMOS). Improving the control of stress of the deposited film improves the control of the resulting drive current of the negative metal oxide semiconductor (NMOS).

A CMOS transistor includes a gate structure that is between a source region and a drain region defined in the semiconductor substrate. The gate structure generally is a gate electrode formed on a gate dielectric material. The gate electrode controls a flow of charge carriers beneath the gate dielectric in a channel region that is between the drain region and the source region to turn the transistor on or off. Disposed proximate the gate stack is a spacer layer, which forms a sidewall on either side of the gate stack. Sidewall spacers serve several functions including electrically isolating the gate electrode from source and drain contacts or interconnects, acting as a barrier to diffusion of dopants such as boron or impurities such as hydrogen, protecting the gate stack from physical degradation during the subsequent processing steps, and providing an oxygen and moisture barrier to protect the gate metal.

Low dielectric constant films in a spacer stack have improved Miller capacitance for improved drive current for the CMOS. If the sidewall spacer is fabricated from a relatively high dielectric constant material, such as a material with a dielectric constant greater than 7, excessive signal crosstalk between adjacent interconnection lines can occur during use of the device containing the completed gate electrode. Although low dielectric constant materials, such as those materials with a dielectric constant below 3, may be employed as a spacer layer, the materials often lack the necessary structural integrity to survive subsequent processing steps or the required imperviousness to dopants such as boron and to oxygen and moisture to protect the gate metal from corrosion.

Deposition chambers are often part of a larger integrated tool to manufacture multiple components on the substrate surface. The chambers are designed to process one substrate at a time or to process multiple substrates. Historically, thermal CVD was performed by heating a substrate by heating the substrate support member to temperatures above 700° C. When performing CVD at high temperatures, the influx of heat to the chamber was the primary design parameter. Current CVD processes operate at lower temperatures to limit the thermal energy applied to the substrates and avoid undesirable results. Lower temperature operation for CVD requires improving heat distribution at the lower temperatures and providing more efficient heat and chemical distribution within the CVD chamber.

Additionally, improved heat distribution is needed at lower substrate support temperatures to prevent the accumulation of deposits of condensed precursors and deposition films on chamber surfaces. The build-up of material on the chamber surfaces is undesirable because it may become friable, deposit on the substrate surface, and degrade the substrate film properties. Also, the material accumulation may increase the cleaning needed between deposition steps and may increase the downtime to clean the system.

Therefore, there is a need for a method for tailoring chemicals to achieve the desired film properties at lower temperatures and for an apparatus for rapid thermal chemical vapor deposition (RTCVD) and low pressure chemical vapor deposition (LPCVD) to form improved silicon containing films.

### SUMMARY OF THE INVENTION

The present invention provides methods and apparatus for low temperature deposition of doped silicon nitride thin films. The present invention provides a CVD chamber that provides uniform heat distribution for low temperature processing and uniform distribution of process chemicals. Furthermore, the improvements include methods for depositing at least one layer comprising silicon and nitrogen on a substrate by heating a substrate, flowing a silicon containing compound into a processing chamber having a mixing region defined by an adapter ring and at least one blocker plate and an exhaust system, heating the adapter ring and a portion of the exhaust system, flowing a hydrogen, germanium, boron, or carbon containing compound into the processing chamber, and optionally flowing a nitrogen containing compound into the processing chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of one embodiment of a chamber.

FIG. 2 is a perspective schematic view of an alternative embodiment of the process kit for a single wafer thermal CVD process chamber and a liquid delivery system for process gas delivery to a chamber.

FIG. 3 is a perspective view of an embodiment of a gas delivery system.

FIG. 4 is an exploded view of various components of a process kit.

FIG. 5 is a top view of a face plate of the invention.

FIG. 6 is a sectional view of one embodiment of an exhaust system.

FIG. 7 is a cross sectional view of one embodiment of a throttle valve heater.

FIG. 8 is a perspective view of an exhaust pumping plate.

FIG. 9 is a perspective view of a cover for an exhaust pumping plate.

FIG. 10 is a perspective view of a slit valve liner.

FIG. 11 is a schematic view of a surface of a substrate that shows where samples were collected across the surface of the substrate.

FIG. 12 is a schematic view of an embodiment of a formed feature.

### DETAILED DESCRIPTION

Embodiments of the invention provide methods and apparatus for depositing a layer on a substrate. The hardware discussion including illustrative figures of an embodiment is presented first. An explanation of process modifications and test results follows the hardware discussion. Chemical vapor deposition (CVD), sub-atmospheric chemical vapor deposition (SACVD), rapid thermal chemical vapor deposition (RTCVD), and low pressure chemical vapor deposition (LPCVD) are all deposition methods that may benefit from the following apparatus and process modifications. Examples of CVD processing chambers that may utilize some of the embodiments of this apparatus and process include the SiNgen™, SiNgen-Plus™, and FlexStar™ chambers which are commercially available from Applied Materials, Inc. of Santa Clara, Calif.

Apparatus

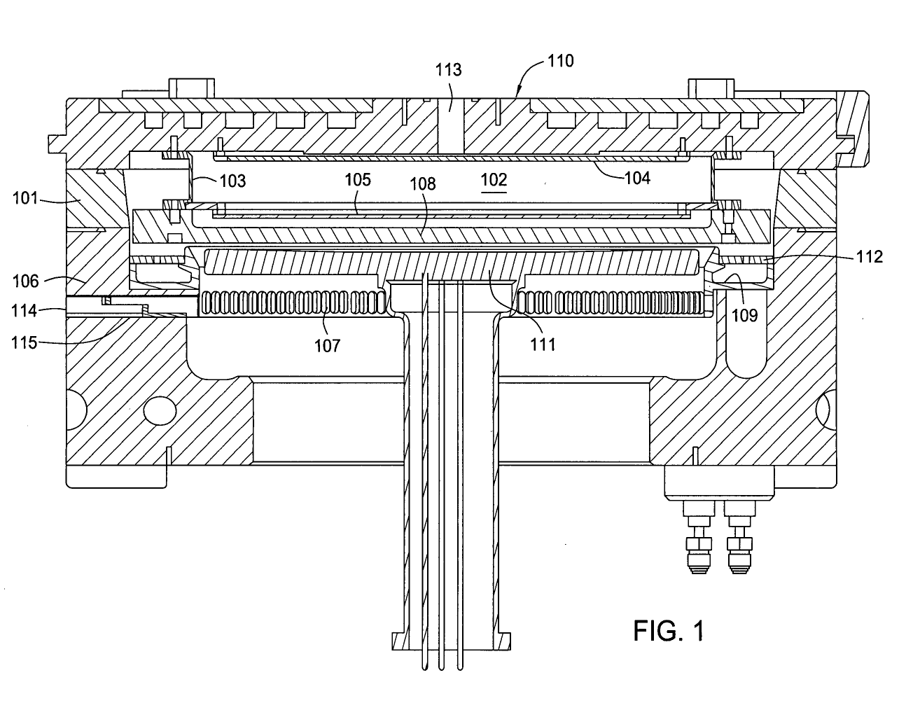

FIG. 1 is a cross sectional view of an embodiment of a single wafer CVD processing chamber having a substantially cylindrical wall 106 closed at the upper end by a lid 110. The lid 110 may further include gas feed inlets, a gas mixer, a plasma source, and one or more gas distribution plates described below. Sections of the wall 106 may be heated. A slit valve opening 114 is positioned in the wall 106 for entry of a substrate.

A substrate support assembly 111 supports the substrate and may provide heat to the chamber. In addition to the substrate support assembly, the base of the chamber may contain additional apparatus further described below, including a reflector plate, or other mechanism tailored to facilitate heat transfer, probes to measure chamber conditions, an exhaust assembly, and other equipment to support the substrate and to control the chamber environment.

Feed gas may enter the chamber through a gas delivery system before passing through a mixer 113 in the lid 110 and holes (not shown) in a first blocker plate 104. The feed gas then travels through a mixing region 102 created between a first blocker plate 104 and a second blocker plate 105. The second blocker plate 105 is structurally supported by an adapter ring 103. After the feed gas passes through holes (not shown) in the second blocker plate 105, the feed gas flows through holes (not shown) in a face plate 108 and then enters the main processing region defined by the chamber wall 106, the face plate 108, and the substrate support 111. Exhaust gas then exits the chamber at the base of the chamber through the exhaust pumping plate 107. Optionally, the chamber may include an insert piece 101 between the chamber walls 106 and the lid 110 that is heated to provide heat to the adaptor ring 103 to heat the mixing region 102. Another hardware option illustrated by FIG. 1 is the exhaust plate cover 12, which rests on top of the exhaust pumping plate 109. Finally, an optional slit valve liner 115 may be used to reduce heat loss through the slit valve opening 114.

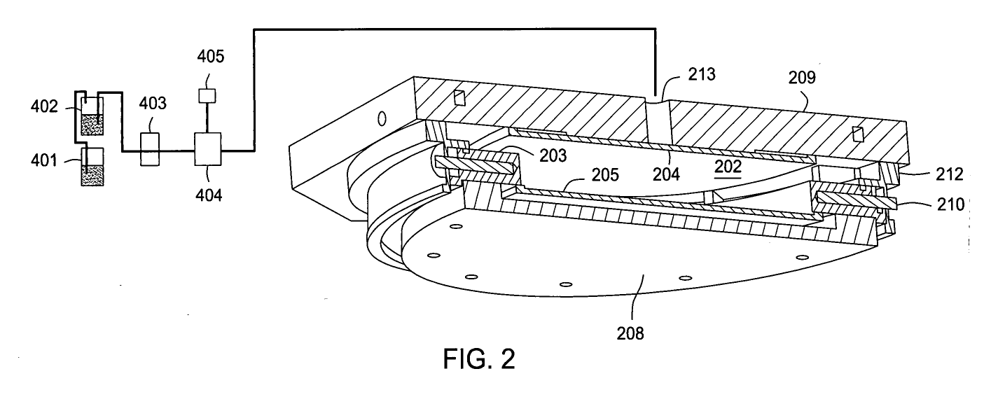

FIG. 2 is an expanded view of an alternative embodiment of the lid assembly. The lid 209 may be separated from the rest of the chamber by thermal insulating break elements 212. The break elements 212 are on the upper and lower surface of heater jacket 203. The heater jacket 203 may also be connected to blocker plate 205 and face plate 208. Optionally, parts of the lid or lid components may be heated.

The lid assembly includes an initial gas inlet 213 to premix the feed gas before entering a space 202 defined by the lid 209, the thermal break elements 212, the heater jacket 203, and the blocker plates 204 and 205. The space 202 provides increased residence time for the reactant gases to mix before entering the substrate processing portion of the chamber. Heat that may be applied by the heater 210 to the surfaces that define the space 202 helps prevent the buildup of raw materials along the surfaces of the space. The heated surfaces also preheat the reactant gases to facilitate better heat and mass transfer once the gases exit the face plate 208 and enter the substrate processing portion of the chamber.

FIG. 2 is also an illustration of the components of a gas feed system for adding an silicon containing compound such as bis(tertiary butylamino)silane (BTBAS) to a CVD chamber. The BTBAS is stored in a bulk ampoule 401. The BTBAS flows from the bulk ampoule 401 to the process ampoule 402 and then flows into the liquid flow meter 403. The metered BTBAS flows into a vaporizer 404, such as a piezo-controlled direct liquid injector. Optionally, the BTBAS may be mixed in the vaporizer 404 with a carrier gas such as nitrogen from the gas source 405. Additionally, the carrier gas may be preheated before addition to the vaporizer. The resulting gas is then introduced to the gas inlet 213 in the lid 209 of the CVD chamber. Optionally, the piping connecting the vaporizer 404 and the mixer 113 may be heated.

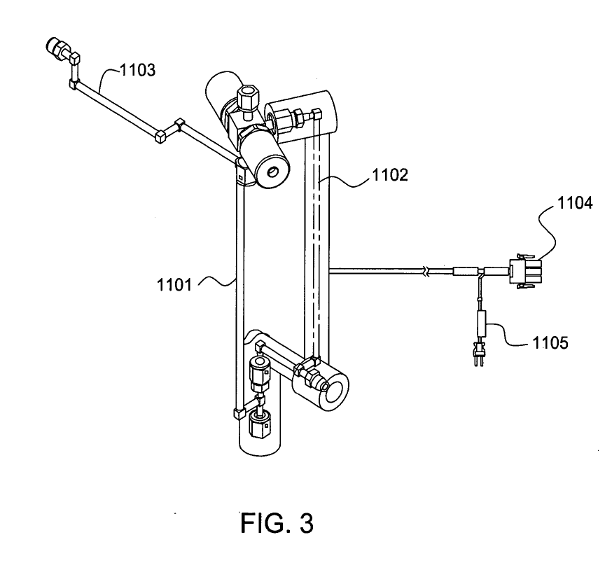

FIG. 3 is a three dimensional view of an embodiment of a gas delivery system. The precursor gas is delivered to the system through line 1103. The clean and vent line 1101 divides the precursor gas from the heated divert line 1102. Portions of the gas and fluid mixture that flow through the heated divert line 1102 flow through convection gauge 1104 and exhaust 1105.

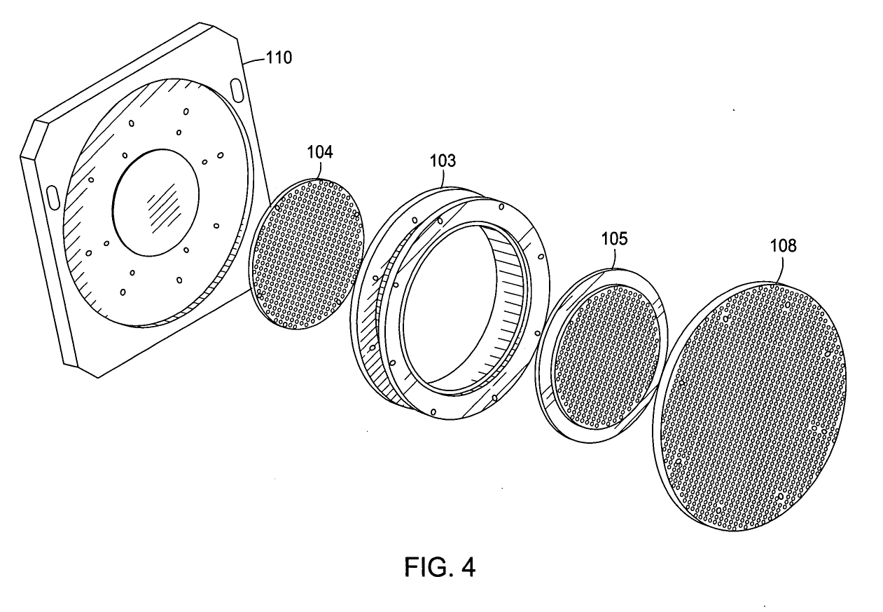

FIG. 4 is an exploded view of the embodiments of the gas feed system shown in FIG. 1. FIG. 4 illustrates how the lid 110, one or more blocker plates 104,105, the adaptor ring 103, and the face plate 108 may be configured to provide a space with heated surfaces for heating and mixing the gases before they enter the processing region of the chamber.

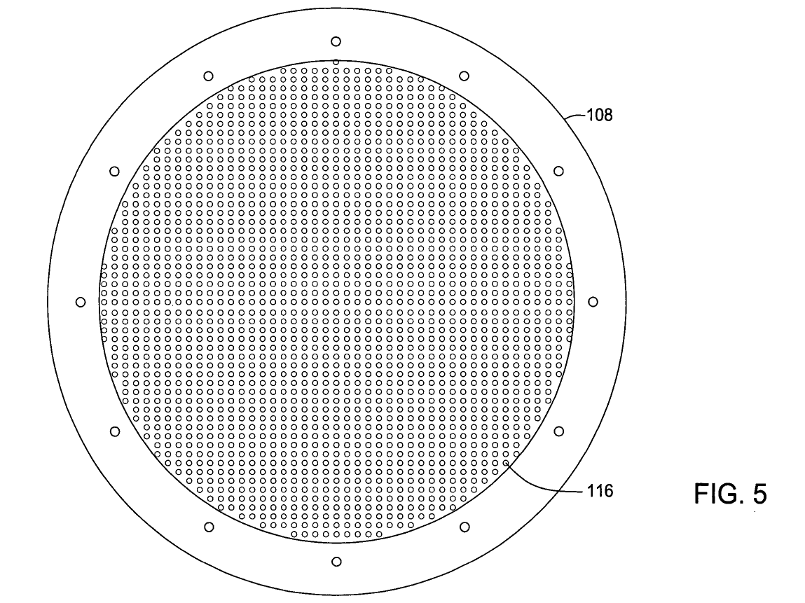

FIG. 5 is an illustration of an embodiment of the face plate 108 of FIG. 1. The face plate 108 is supported by the adapter ring 103. The face plate 108 is connected to the adapter ring 103 by screws and is configured with holes 116 arranged to create a desirable gas inlet distribution within the processing region of the chamber.

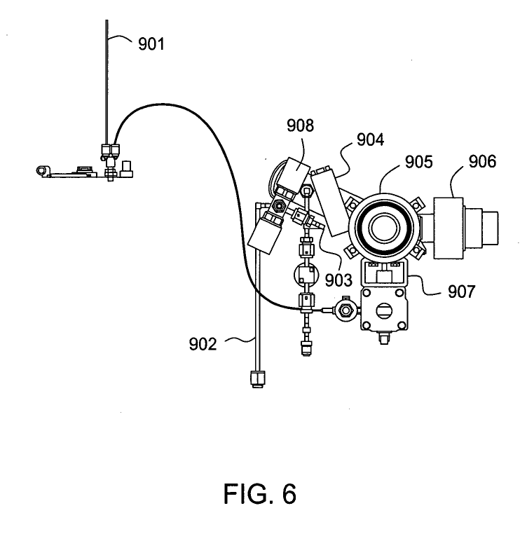

FIG. 6 is a sectional view of an embodiment of an exhaust system. Conduit 901 supplies clean dry air to dilute the final exhaust gas as it enters an abatement system. The precursor gas line has a clean or vent line 902 and divert line 903. The convection gauge 904 is in communication with the divert line 903 and ball valve 905. The ball valve 905 is in communication with the throttle valve 906 and the spool piece 907. Ball valve 905 may be a ball type ISO valve or a JALAPEÑO™valve. JALAPEÑO™valves are compact heated vacuum valves and are commercially available from HPS Products of Wilmington, Mass. A valve heater supplies heat to the ball valve 905.

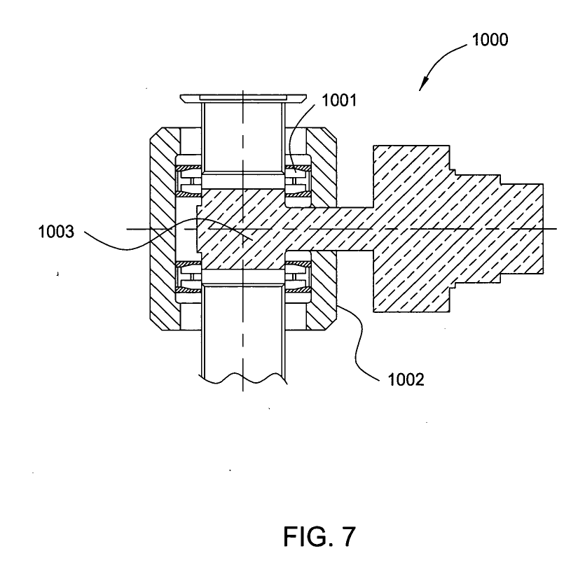

FIG. 7 provides a cross sectional view of an embodiment of a throttle valve 1000. Clamps 1001 extend around the valve 1000. Throttle valve heater jacket 1002 provides heat to the exterior of valve 1000, indirectly heating the cavity 1003 of the valve 1002.

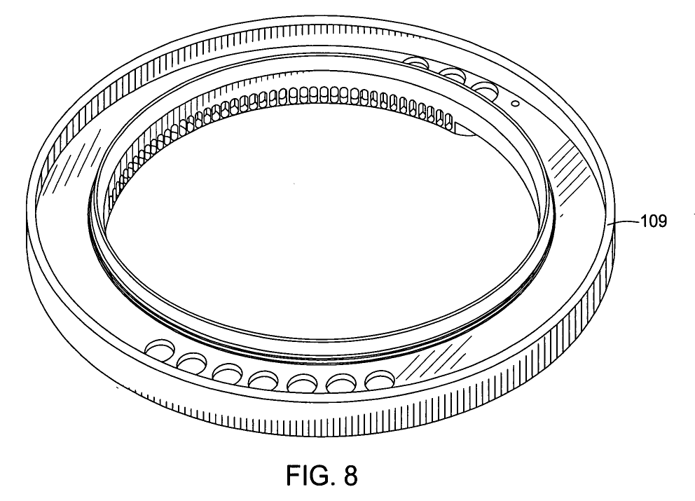

FIG. 8 is a three dimensional schematic view of one embodiment of the exhaust pumping plate 109 to control the flow of exhaust from the processing region of the chamber. A section of exhaust pumping plate 109 consisting of a skirt, shown as a series of slit-shaped holes, help compensate for heat loss at the slit valve area.

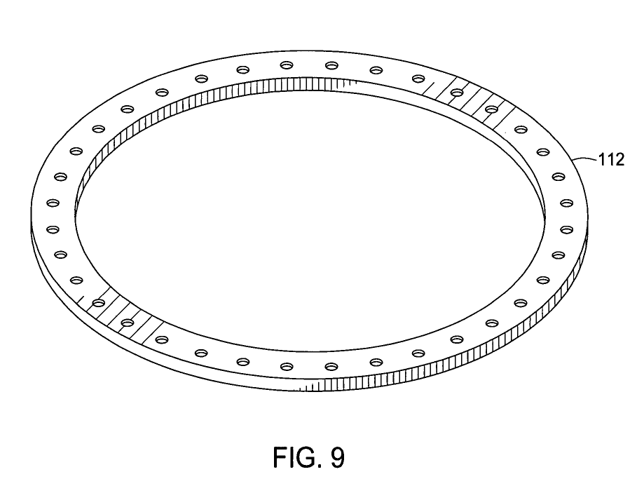

FIG. 9 is a three dimensional schematic view of an exhaust plate cover 112 for the exhaust plate 109. The cover 112 is designed with optimized, nonuniform holes to provide even gas distribution or alternatively to provide purposely uneven gas distribution to compensate for heat loss imbalance.

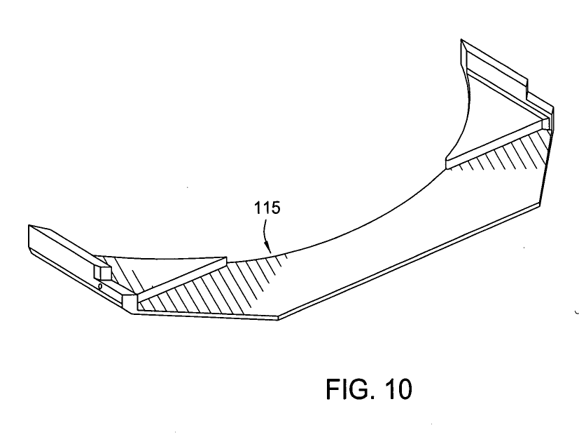

FIG. 10 is a three-dimensional view of one embodiment of the slit valve liner 115 of FIG. 1. The slit valve liner 115 reduces heat loss through the slit valve opening 114 by directing process gas flow and reducing heat transfer through the slit valve.

Structure

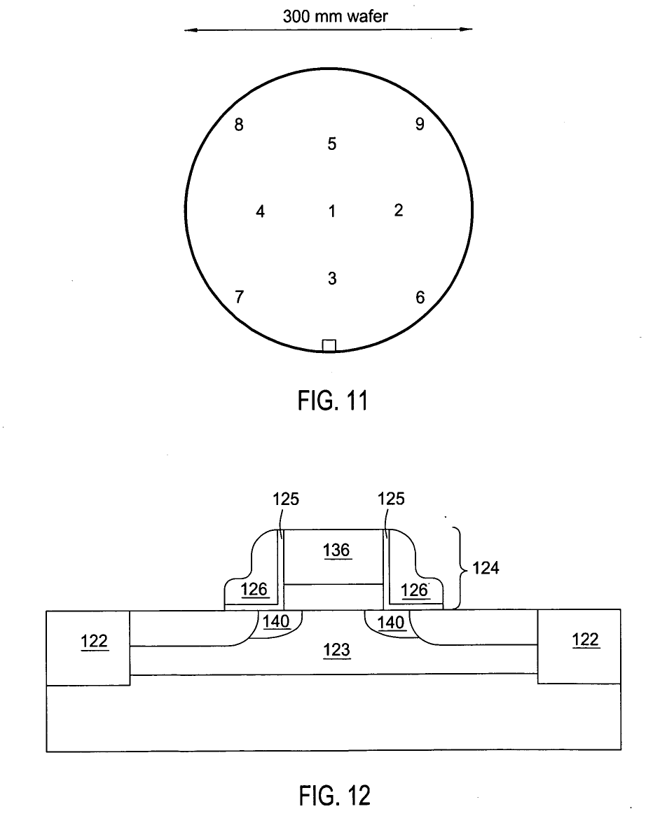

FIG. 12 illustrates a transistor having a gate structure formed according to one embodiment of the invention. A plurality of field isolation regions 122 are formed in a substrate 100. The plurality of field isolation regions 122 isolate a well 123 of one type conductivity (e.g., p-type) from adjacent wells (not shown) of other type conductivity (e.g., n-type). A gate dielectric layer is formed on the substrate 100 and on well 123. Typically, gate dielectric layer may be formed by depositing or growing a layer of a material such as silicon oxide (SiOₙ) and/or silicon oxynitride, having a dielectric constant less than about 5.0. Recent advances in gate dielectric technology indicate that higher dielectric constant materials (K>10) are desirable for forming gate dielectric layer. Examples of suitable materials to be employed therefore include, but are not limited to, metal oxides (AI₂O₃, ZrO₂, HfO₂, TiO₂, Y₂O₃, and La₂O₃), ferroelectrics (lead zirconate titanate (PZT) and barium strontium titanate (BST)), amorphous metal silicates (HfSi_{x,O}_{y and ZrSi}ₓO_{y}), amorphous silicate oxides (HfO₂, and ZrO₂), and paralectrics (BaₓSr₁₋ₓTiO₃ and PbZrₓTi₁₋ₓO₃). High k layers containing these materials may be formed by various deposition processes.

Further, an electrically conductive gate electrode layer 136 is blanket deposited over gate dielectric layer. Generally, the gate electrode layer 136 may comprise a material such as doped polysilicon, undoped polysilicon, silicon carbide, or silicon-germanium compounds. However, contemplated embodiments may encompass a gate electrode layer 136 containing a metal, metal alloy, metal oxide, single crystalline silicon, amorphous silicon, silicide, or other material well known in the art for forming gate electrodes.

A hard-mask layer (not shown), such as a nitride layer, is deposited via a CVD process over electrically conductive layer 136. A photolithography process is then carried out including the steps of masking, exposing, and developing a photoresist layer to form a photoresist mask (not shown). The pattern of the photoresist mask is transferred to the hard-mask layer by etching the hard-mask layer to the top of the gate electrode layer 136, using the photoresist mask to align the etch, thus producing a hard-mask (not shown) over the gate electrode layer 136.

The structure is further modified by removing the photoresist mask and etching the gate electrode layer 136 down to the top of the dielectric layer, using the hard-mask to align the etch, thus creating a conductive structure including the remaining material of gate electrode layer 136 underneath the hard-mask. This structure results from etching the gate electrode layer 136, but not the hard-mask or gate dielectric layer. Continuing the processing sequence, gate dielectric layer is etched to the top of the substrate 100 and to the tops of the isolation regions 122. The gate electrode 136 and the gate dielectric together define a composite structure 124, sometimes known as a gate stack, or gate, of an integrated device, such as a transistor.

In further processing of the gate stack, shallow source/drain extensions 140 are formed by utilizing an implant process. The gate electrode 136 protects the substrate region beneath the gate dielectric from being implanted with ions. A rapid thermal process (RTP) anneal may then be performed to drive the tips 140 partially underneath the gate dielectric.

Next, a conformal thin oxide layer 125 is deposited over the entire substrate surface. This oxide layer is used to protect the silicon surface from the spacer layer 126, which is typically a silicon nitride layer. The conformal thin oxide layer is typically deposited in a low pressure chemical vapor deposition chamber at high temperature (>600° C.). The thin oxide layer relaxes the stress between the silicon substrate and the nitride spacer and it also protects the gate corners from the silicon nitride spacer by providing another layer of material. If low k and non-silicon-nitride material is used as sidewall spacer, this conformal thin oxide layer 125 can possibly be eliminated or replaced by another low k material.

In one embodiment of the invention, a spacer layer 126, with a thickness in the range between about 200 Å to about 1000 Å, preferably between about 400 Å to about 800 Å, is blanket deposited over the top of the composite structure 124 and along the entire length of the sides of the gate stack 124, including the entire length of the sidewalls of the gate electrode 136 and the gate dielectric. At the same time, the spacer layer 126 is deposited on top of any exposed portion of the substrate 100 or isolation regions 122. Conventional spacer layer 126 is a silicon nitride layer deposited by thermal CVD. For advanced device manufacturing, if the dielectric constant of the spacer layer 126 or oxide layer 125 is too high, the resulting structure often results in excessive signal crosstalk. In addition, thermal CVD processes used to deposit silicon nitride often require high deposition temperature. The high deposition temperature often results in high thermal cycle and an altered dopant profile of tip 140. Therefore, it is desirable to have a low dielectric constant spacer layer deposition process with lower deposition temperature.

Silicon Nitride Films

Silicon nitride films may be chemical vapor deposited in the chambers described herein by reaction of a silicon precursor with a nitrogen precursor. Deposition at lower temperatures requires closer scrutiny of the precursor gases to select a gas with lower likelihood of condensation along chamber surfaces and a higher probability of reacting with other precursors to form a film on the substrate surface. Silicon precursors that may be used include dichlorosilane (DCS), hexachlorodisilane (HCD), bis(tertiary butylamino)silane (BTBAS), silane (SiH₄), disilane (Si₂H₆), and many others. Nitrogen precursors that may be used include ammonia (NH₃), hydrazine (N₂H₄), and others. For example, SiH₄ and NH₃ chemistry may be used.

During processing, SiH₄ dissociates into SiH₃, SiH₂ primarily, and possibly SiH. NH₃ dissociates into NH₂, NH, and H₂. These intermediates react to form SiH₂NH₂ or SiH₃NH₂ or similar amino-silane precursors that diffuse through the gas boundary layer and react at or very near the substrate surface to form a silicon nitride film.

Testing of varied NH₃ flow rates indicates that increasing the NH₃ flow rate relative to the flow rate of the other precursors enhanced the deposition of films. For example, conventional systems may operate with flow rates of NH₃ to SiH₄ in a ratio of 60 to 1. Test results indicate a conventional ratio of 60 to 1 up to 1000 to 1 provides a uniform film when spacing between the lid and the final gas distribution plate is also increased. It was further found that using a spacing of 850-1000 mils between the final gas distribution plate and the substrate enhanced the film uniformity compared to films deposited at 650 mils.

Also, tests to determine the acceptability of disilane and ammonia as precursors were performed. The deposition of silicon nitride at 525° C. had acceptable levels of in-film particle adders and dielectric constant measurements. This film also provided protection from boron diffusion across the spacer or oxide layer.

Furthermore, tests were performed using silazane (SiN(H₂)) as a silicon containing precursor. The films formed using silazane as the precursor required a lower thermal budget and had film properties that were comparable to films deposited using disilane or other silicon containing precursors.

Silicon Germanium Nitride Films

Depositing a film with reduced hydrogen content may be desirable. The presence of hydrogen in films increases the diffusion of boron, reducing the ability to tune the conductivity of a film. To deposit a film with reduced hydrogen content, using a silicon-containing precursor other than silane or disilane may be required. Also, adding germane (GeH₄) or digermane (Ge₂H₆) may be beneficial. Germanium enhances surface hydrogen desorption and reduces in-film hydrogen content. Desorption of hydrogen is encouraged by the presence of germanium because the hydrogen silicon chemical bond is stronger than the hydrogen-germanium chemical bond. The transfer of hydrogen from a silicon atom to a germanium atom is a fast transfer. Germanium has a lower surface energy than silicon, so germanium migrates to the surface. Thus, germanium provides the hydrogen with a low energy barrier path for thermal desorption of hydrogen from the surface in the form of hydrogen molecules. Additionally, germanium enhances the film growth rate, thus facilitating lower temperatures for deposition and decreasing the overall system thermal budget. This process has the advantage of not requiring ammonia as the nitrogen containing precursor.

Two deposition techniques may be selected to use germanium in the deposition process. The silicon-containing gas, the nitrogen-containing gas, and the germanium-containing gas can be introduced into the system at the same time. Alternatively, the gases could be introduced individually with a brief, limited overlap of two gases introduced at the same time. For example, germanium-containing gas is introduced into the chamber with a brief overlap of silicon-containing gas at the end of the germanium-containing gas exposure. Then, the silicon-containing gas is introduced with no other precursor. Toward the end of the period of exposure of the silicon-containing precursor, the nitrogen-containing precursor is introduced into the chamber and continues to flow into the chamber after the silicon-containing precursor is no longer flowing into the chamber. Thus, the germanium deposited in a first fraction of the deposition step would migrate to the surface as silicon and nitrogen atoms were deposited. Thus, less germanium would remain incorporated in the silicon nitride film. Additionally, an oxidizing gas such as nitrous oxide or oxygen could be applied to the substrate to form germanium oxides which are volatile. Thus, when combining the introduction of germanium and an oxidizing gas in a staggered gas introduction regimen, the resulting film would have lower hydrogen content from the introduction of germanium and lower germanium content from introduction of the oxidizing gas.

Boron Doped Silicon Nitride Films

In one embodiment, boron doped silicon nitride films may be deposited. Using boron as a dopant is desirable for low temperature deposition. Adding a boron doped layer to a stack of films may lower the overall dielectric constant. For example, the typical dielectric constant of silicon nitride films is 7.1 and using BTBAS for a silicon nitrogen carbon hydrogen film lowers the dielectric constant of the film to less than 5.5. Adding a boron silicon nitrogen hydrogen layer to a stack reduces the overall dielectric constant to less than 4.5.

BTBAS or other silicon containing precursor; ammonia, or other nitrogen containing precursor; and BCI₃, diborane, or other boron containing precursor may be used to deposit a boron doped silicon nitride film. The ammonia or other nitrogen containing precursor may be excited by utilizing a UV lamp.

Utilizing a boron doped film provides a way to control the stress of the deposited stack by inducing strain in the N-channel to improve the drive current of the NMOS. To obtain a film with a lower dielectric constant and an increase in tensile stress, four approaches are available. 1. Flow disilane, UV excited ammonia, and diborane into a single substrate chamber utilizing RTCVD. 2. Perform RTCVD to deposit a silicon nitrogen hydrogen film, then perform RTCVD to deposit a boron nitrogen hydrogen film. 3. Flow disilane, UV excited ammonia, and diborane utilizing LPCVD. 4. Perform LPCVD to deposit a silicon nitrogen hydrogen film, then perform LPCVD to deposit a boron nitrogen hydrogen film.

Because it has a lower dielectric constant, boron doped silicon films have been used in back end of the line (BEOL) interlayer isolation and front end of the line (FEOL) gate spacer at deposition temperatures greater than 630° C. However, when the chamber surfaces are heated, such as by using the chamber surface heating system described in FIGS. 1 to 10 above, boron doped silicon films can be successfully deposited at about 450° C. using disilane, ammonia, and diborane as the precursor gases.

Additionally, when boron doped silicon nitride was deposited using disilane at 550° C., the stress was unchanged (about 1.4 GPa) compared to higher temperature deposited films using disilane, the deposition rate was 142 to 265 Å/min, and the refractive index was 1.98 to 2.04.

Carbon Doped Silicon Nitride Films

In one embodiment, BTBAS may be used as a silicon containing precursor for deposition of carbon doped silicon nitride films in the chambers described herein. The following is one mechanism that may be followed to produce a carbon doped silicon nitride film with t-butylamine byproducts. The BTBAS may react with the t-butylamine to form isobutylene.
3C₈H₂₂N₂Si+NH₃=>Si₃N₄+NH₂C₄H₉

The BTBAS reaction to form the carbon doped silicon nitride film may be reaction rate limited, not mass transfer limited. Films formed on a patterned substrate may uniformly coat the exposed surfaces of the patterned substrate. BTBAS may have less pattern loading effect than the conventional silicon precursors. It is believed that the pattern loading effect experienced with silicon containing precursors other than BTBAS is due to the mass transfer limitations of those precursors.

Using BTBAS as a reactant gas also allows carbon content tuning. That is, by selecting operating parameters such as pressure and precursor gas concentration, the carbon content of the resulting film may be modified to produce a film with uniform carbon concentration across the diameter of a substrate. BTBAS may be added to the system at a rate of 0.05 to 2.0 gm/min and typical systems may use 0.3-0.6 g/min.

Table 1 gives an element by element composition of samples taken from various points across a substrate for different process conditions. The element composition of the samples was measured by nuclear reaction analysis and Rutherford backscattering spectroscopy. FIG. 11 is a drawing of a substrate showing where the samples were collected across the surface of the substrate. For example, location 1 data represented the information at the center of the substrate. Location 9 data represents data collected at the periphery of the substrate, and location 4 represents data collected across the midpoint of the radius of the substrate.

TABLE 1
Atomic Composition Based on Location across Substrate Surface

| | C | N | O | Si |
|---|---|---|---|---|
| Slot 3, Spot 1 (0 mm, 0 deg.) | 10.8 | 37.4 | 6.4 | 45.3 |
| Slot 3, Spot 2 (75 mm, 0 deg.) | 10.5 | 37.5 | 6.6 | 45.4 |
| Slot 3, Spot 3 (75 mm, 90 deg.) | 10.5 | 37.4 | 6.8 | 45.4 |
| Slot 3, Spot 4 (75 mm, 180 deg.) | 10.8 | 37.6 | 6.7 | 45.0 |
| Slot 3, Spot 5 (75 mm, 270 deg.) | 10.7 | 38.1 | 6.7 | 44.5 |
| Slot 3, Spot 6 (145 mm, 45 deg.) | 11.1 | 37.6 | 6.7 | 44.7 |
| Slot 3, Spot 7 (145 mm, 135 deg.) | 10.0 | 37.8 | 6.5 | 45.7 |
| Slot 3, Spot 8 (145 mm, 225 deg.) | 10.4 | 37.6 | 6.3 | 45.6 |
| Slot 3, Spot 9 (145 mm, 315 deg.) | 11.2 | 37.1 | 6.9 | 44.8 |
| Average | 10.7 | 37.6 | 6.6 | 45.2 |
| St. Dev. | 0.4 | 0.3 | 0.2 | 0.4 |
| % St. Dev. | 3.4 | 0.7 | 2.9 | 0.9 |

Table 1 illustrates that the variation in carbon content across the surface of the substrate was 3.4% based on XPS testing results. It was found that carbon doped silicon nitride films having from 2 to 18 atomic percentage carbon were deposited at enhanced rates in the chambers described herein.

Using BTBAS as the silicon containing precursor offers several resulting film property advantages. Increasing the carbon content of the film can improve the dopant retention and junction profile, resulting in improved performance in the positive channel metal oxide semiconductor (PMOS) part of the device. The process parameters may also be tailored when combined with the use of BTBAS to facilitate improved stress profile. Enhanced film stress improves the device performance for the negative channel metal oxide semiconductor (NMOS) part of the device. Film stress properties are influenced by tailoring the chamber pressure, total feed gas flow, the NH₃ and BTBAS feed gas ratio, and the volume fraction of BTBAS.

Additional experimental results indicate that at 675° C. the standard deviation for film nonuniformity was less than 1.5 percent. The standard deviation of the composition of the film nonuniformity over a temperature range of 645 to 675° C. was less than 1 percent. The particle contamination was less than 30 particles at less than or equal to 0.12 μm.

The wet etch ratio is lower when low concentration NH₃ and low pressure are selected. The pressure range tested was 50 to 275 Torr. The wet etch ratio was measured as less than 0.3. The wet etch ratio of the film was calculated by comparing the film etch to a thermal oxide with 100:1 HF RMS roughness at 400 Å equal to 0.25 nm.

The film deposition rate over 625 to 675° C. was 125 to 425 Å. The deposition rate was higher when higher concentration of BTBAS, lower NH₃ concentration, and higher pressure and temperature were selected.

The hydrogen concentration of the film was less than 15 percent. It is estimated that the hydrogen is mostly bonded within the film as N—H. The carbon content of the film was 2 to 18 percent.

The observed stress was 1 E9 to 2 E10 dynes/cm² (0.3 to 1.7 GPa) for enhanced NMOS I-drive. The stress was higher with high concentrations of NH₃, low concentration of BTBAS, and low pressure.

The measured refractive index over the same temperature range was 1.8 to 2.1. The refractive index was higher when the system was operated at lower pressure and lower BTBAS concentration.

Also, the observed or estimated carbon concentration ranged from 3 to 16 percent. It was highest when the NH₃ concentration was low and the concentration of BTBAS was high.

Finally, an additional analysis was performed using three BTBAS configurations. Table 2 provides flow rates, concentration, and resulting film properties for three configurations.

TABLE 2
Three BTBAS Configurations and the Resulting Film Properties.

| | | recipe | | |
|---|---|---|---|---|
| | | C 5-6% | C 8-9% | C 12-13% |
| | | (predicted) | (tested) | (predicted) |
| deposition rate | (Å/min) | 315.4 | 266.9 | 399.4 |
| dep time | (sec) | 136 | 160 | 106 |
| target thickness | (Å) | 700 | 700 | 700 |
| monitor film thickness | (Å) | 714.97 | 711.715 | 705.545 |
| monitor N/U 1-sigma | (%) | 2.371 | 1.437 | 1.492 |
| VR | | 0.98 | 0.98 | 0.98 |
| RI | | 1.821 | 1.82 | 1.817 |
| BTBAS consumption | (grams/500 | 0.897 | 0.571 | 0.782 |
| | Ang film) | | | |
| stress | (GPa) | | 1.2 | |
| WERR | | | 0.5 | |
| heater temp | (C.) | 675 | 675 | 675 |
| chamber pressure | (Torr) | 162.5 | 275 | 160 |
| BTBAS flow | (grams/min) | 0.566 | 0.305 | 0.625 |
| | (sccm) | 74.2 | 40 | 81.9 |
| NH₃ flow | (sccm) | 300 | 40 | 40 |
| N₂ carrier flow | (slm) | 2 | 2 | 2 |
| N₂ flow | (slm) | 1.7 | 3 | 2 |
| total top gas flow | (slm) | ˜4 | ˜5 | ˜4 |
| N₂ bottom flow | (slm) | 3 | 3 | 3 |
| spacing | (mils) | 700 | 700 | 700 |

The C 5-6% and C 12-13% configurations have predicted values. The C 8-9% values are experimental results. VR indicates the ratio of voltage applied to the two zones of the substrate heater. RI indicates the refractive index. WERR is the wet etch rate ratio.

Four examples were tested. Pressure, temperature, spacing, flow rate, and other conditions are shown in Table 3. Recipe 1 shows a set of operating conditions at lower BTBAS concentration than the other examples. Recipe 2 shows operation at low temperature. Recipe 3 shows conditions providing the lowest deposition rate, the lowest wet etch ratio, and temperature and Recipe 4 shows operating parameters for the lowest pressure. In the examples, the substrate heater temperature was 675 to 700° C. and the pressure of the chamber was 50 to 275 Torr.

TABLE 3
Operating Conditions for Testing BTBAS Performance

| | recipe name | | | |
|---|---|---|---|---|
| | #1 | #2 | #3 | #4 |
| substrate temperature | ˜670 | ˜655 | ˜660 | ˜675 |
| (° C.) | | | | |
| heater temp (° C.) | 675 | 675 | 675 | 700 |
| pressure (Torr) | 275 | 160 | 80 | 50 |
| NH₃ (sccm) | 80 | 80 | 80 | 80 |
| BTBAS (grams/min) | 0.61 | 1.2 | 1.2 | 1.2 |
| BTBAS (sccm) | 78 | 154 | 154 | 154 |
| N₂-carrier top (slm) | 4 | 4 | 4 | 4 |
| N₂-dep-top (slm) | 10 | 10 | 6 | 6 |
| N₂-bottom (slm) | 10 | 10 | 10 | 10 |
| spacing (mills) | 700 | 700 | 700 | 700 |
| deposition rate (A/min) | 230 | 250 | 170 | 250 |
| BTBAS consumption | 0.27 | 0.48 | 0.71 | 0.48 |
| (grams/100 A film) | | | | |
| Wet etch rate ratio | 25 | 16 | 11 | 12 |
| (%) | | | | |
| stress (dynes/cm²) - | 1.54 | 1.54 | 1.51 | 1.67 |
| 500 A film | | | | |
| RI | 1.865 | 1.885 | 1.935 | 1.985 |
| thickness 1 sigma N/U | 1.55 | 1.55 | 1.50 | 1.90 |
| (%) | | | | |

PLE on UMC 90 nm chip by TEM

| | | | | |
|---|---|---|---|---|
| sidewall (%) | 7 | 9 | 3 | 3 |
| bottom (%) | 7 | 3 | 3 | 3 |

Utilizing hydrogen as an additional component to the CVD reaction provides enhanced deposition rates at lower temperatures. For example, up to 70 percent increase in deposition rate can be obtained with a process that incorporates hydrogen versus a process that does not. An example of a process that incorporates hydrogen can be the CVD reaction of BTBAS and ammonia and hydrogen.

Additional testing of a hydrogen containing catalyst in combination with BTBAS indicates that the silicon nitride deposition rate increases 30 to 70 percent when including the hydrogen containing catalyst. This improved deposition rate yielded films with no significant change in wet etch rate or refractive index. The films also had no significant change in film composition.

Germanium and Carbon Doped Silicon Nitride Films

Using BTBAS or other larger molecule silicon containing precursors compared to disilane or silane allows deposition at lower temperatures. Including a germanium-containing precursor with the silicon-containing precursor is desirable for low temperature silicon nitride film deposition. A silicon germanium nitride film was tested to determine its properties.

TABLE 4
Comparison of Silicon Nitride Films Deposited
at Varied Temperature and Germane Flow Rates

| Precursor | Temp. (° C.) | Thickness (Å) | R.I. | Dep. Rate (Å/min.) |
|---|---|---|---|---|
| BTBAS | 675 | 578 | 1.814 | ˜260 |
| BTBAS + 25 | 600 | 578.4 | 1.952 | 96.3 |
| sccm GeH₄ | | | | |
| BTBAS + 25 | 500 | 497 | 1.731 | 33.1 |
| sccm GeH₄ | | | | |

The BTBAS flow rate for Table 4 is 305 mg/min for a 300 mm substrate. The thickness and refractive index, R. I., were measured using a KLA-Tenor F-5 ellipsometer, available from KLA-Tenor of San Jose, Calif. Dep. Rate is the rate of film deposition for the 300 mm substrate.

TABLE 5
Stress Measurement of Silicon Nitride Films Deposited
at Varied Temperature and Germane Flow Rates

| Recipe | Temperature (° C.) | Thickness (Å) | Stress (MPa) |
|---|---|---|---|
| BTBAS BKM | 675 | 578 | T, 332 |
| BTBAS BKM + | 600 | 578 | T, 379 |
| 25 sccm GeH4 | | | |
| BTBAS BKM + | 500 | 497 | T, 306 |
| 25 sccm GeH4 | | | |

The BTBAS flow rate for Table 5 is 305 mg/min for a 300 mm substrate. The thickness was measured using a KLA-Tenor F-5 ellipsometer. The stress of the film was measured using a FS5 stress measurement tool.

When deposited using germane, BTBAS, and ammonia as the precursors at a temperature of about 500° C. to about 675° C., the film had an acceptable refractive index of 1.7 to 1.9 and deposition rate of more than 100 Å/minute, but greater than 10,000 in-film particle adders were observed. When the process was repeated without ammonia (using the amino group in BTBAS as the nitrogen source), less than 100 in-film particle adders were observed. The refractive index was measured at about 1.8 to about 2.0 and a deposition rate of about 100 Å/min was observed. The wet etch rate in HF was 200:1. The film deposited at 550° C. with 50 sccm germane had a 1:1:1:1:1 content ratio of Si:Ge:N:C:H using RBS analysis. The stress of the film was about 50 MPa tensile stress to 50 MPa compressive stress.

Introducing germane into the system in higher quantities, such as 150 sccm and 300 sccm produced deposition rates of about 700 Å/min for the 150 sccm germane at 550° C. and about 1,000 Å/min for the 300 sccm germane at 520° C. The refractive index was observed at 1.8 to about 2.0 for all three concentrations of germane.

The carbon and germanium doped silicon nitride film may be deposited at about 400° C. to about 675° C. and about 225 Torr to about 235 Torr. The flow rate of BTBAS may be about 155 to 610 mg/min. and the flow rate of germane may be about 0 to about 250 sccm. The flow rate of ammonia may be about 0 to about 500 sccm. The total flow into the top of the system is 5 slm.

Additionally, using BTBAS with germane and no ammonia as the precursors for silicon nitride deposition resulted in films with acceptable refractive index and high wet etch rate results. When deposited at 500° C., the film had a refractive index of 1.65 to 1.85 and a deposition rate of 80 to 140 Å/min. When deposited at 550° C., the deposition rate is greater than 300 Å/min and the wet etch rate ratio to thermal oxide is approximately 0 Å/min.

Carbon and Boron Doped Silicon Nitride Films

Utilizing a carbon and boron doped silicon nitride film may allow improved control of implant diffusion and reduce deactivation of dopants in the substrate for low temperature film deposition. The dielectric constant and stress of a resulting film stack may be tailored by depositing thin film layers of multiple films. For example, a carbon source and a boron source may be used to deposit a carbon and boron doped silicon nitride film. Also, the precursors may be deposited alternatively such that a silicon nitride hydrogen carbon film is deposited or silicon nitride hydrogen and boron nitride hydrogen films are deposited alternatively. Thus, a silicon nitride hydrogen carbon boron or silicon nitride hydrogen boron film is deposited. If the film layers are deposited alternatively, silicon nitride hydrogen carbon/boron nitrogen hydrogen stacks or silicon nitrogen hydrogen/boron nitrogen hydrogen stacks are formed. Pulsing the silicon and boron sources can be used to form multiple stacks.

To obtain a film with a lower dielectric constant and an increase in tensile stress, four approaches are recommended. 1. Flow BTBAS, UV excited ammonia, and diborane into a single substrate chamber utilizing RTCVD. 2. Perform RTCVD to deposit a silicon nitrogen carbon hydrogen film, then perform RTCVD to deposit a boron nitrogen hydrogen film, pulsing the silicon containing precursors alternatively. 3. Flow BTBAS, UV excited ammonia, and diborane utilizing LPCVD. 4. Perform LPCVD to deposit a silicon nitrogen carbon hydrogen film, then perform LPCVD to deposit a boron nitrogen hydrogen film.

When performing RTCVD, the precursors should be deposited for about 2 to about 5 minutes for a resulting film thickness of 1000 Åor less. The pressure of the chamber should be selected in the range of about 10 to about 350 Torr and the total gas flow should be selected in the range of about 1 to about 10 slm. When tailoring the resulting film for a low dielectric constant, the temperature should be controlled to less than about 550° C. When tailoring the resulting film for high tensile stress, the temperature should be controlled to less than about 475° C. The silicon containing precursor is preferably disilane or BTBAS, the nitrogen containing precursor is preferably ammonia or UV excited (remotely or directly) ammonia and the boron source is preferably diborane. The diborane may be diluted by nitrogen, hydrogen, argon, or helium. The diluent gas may be nitrogen, argon, or helium.

When performing LPCVD, similar process conditions and chemicals as those selected for RTCVD may be used. The precursors should be deposited for about 2 to about 5 hours for a resulting film thickness of 1000 Åor less. The pressure of the chamber should be selected in the range of about 100 to about 700 mTorr and the total gas flow should be selected in the range of about 1 to about 10 slm. When tailoring the resulting film for a low dielectric constant, the temperature should be controlled to less than about 500° C. When tailoring the resulting film for high tensile stress, the temperature should be controlled to less than about 425° C. The silicon containing precursor is preferably disilane or BTBAS, the nitrogen containing precursor is preferably ammonia or UV excited (remotely) ammonia and the boron source is preferably diborane. The diborane may be diluted by nitrogen, hydrogen, argon, or helium.

In experiments, utilizing boron and carbon to dope silicon nitride films increased tensile stress by 20 percent. Also, when the films were deposited from 550 to 675° C. with 50 to 300 sccm of diborane to 305 mg/m BTBAS and 40 sccm ammonia at 275 Torr, the deposition rate of the film was 435 Å/min at 675° C. and 150 sccm diborane and 211 Å/min at 550° C. and 300 sccm diborane. Thus, the film deposition rate increases as the flow of diborane increases. Also, the refractive index and film stress also have favorable trends as the diborane flow rate increases. From plotting the capacitance as a function of probe voltage for a film deposited with 300 sccm diborane and 305 mg/m BTBAS at 550° C., the measured dielectric constant is 4.5. The deposition rate is 142 to 265 Å/min and the wet etch rate in 200:1 HF is 1 Å/min, which is lower than comparable higher temperature BTBAS processes. The refractive index is 1.98 to 2.04. The dielectric value of the film must be tuned by the content of boron in the film.

When BTBAS, ammonia, and diborane were precursors in a system at 525° C., the deposited film had acceptable levels of in-film particle adders. The dielectric constant was also acceptable.

TABLE 6
Stress Measurement for BTBAS and Disilane Based Films

| Precursors | Temperature (C.) | Stress (MPa) |
|---|---|---|
| BTBAS | 675 | T, 1509-1537 |
| Si₂H₆ | 550 | T, 1360 |
| Si₂H₆ + 50 sccm diborane | 550 | T, 1334 |
| Si₂H₆ + 150 sccm diborane | 550 | T, 1227 |
| Si₂H₆/B—SiN/Si₂H₆ Stack | 550 | T, 1394 |

Table 6 compares the stress and deposition temperature for films deposited using BTBAS, disilane, or one of the silicon containing precursors in combination with ammonia and optionally diborane. The low temperature (550° C.) disilane in combination with 150 sccm diborane provided the film with the lowest stress. Additional testing indicates that the film deposition rate increases as the flow rate of diborane increases. The refractive index and film stress also have more desirable results as the flow rate of diborane increases.

RBS/HFS testing and FTIR analysis were also performed on similar films. The RBS/HFS testing indicates the measured film had experimental results that were comparable to the theoretical results. The composition of the film was 15 atomic percent hydrogen, 34.6 atomic percent nitrogen, 25.9 atomic percent silicon, 17.0 atomic percent boron, 5.2 atomic percent carbon, and 2.3 atomic percent oxygen. The FTIR analysis comparing films deposited with BTBAS, ammonia, and diborane at 675° C. and 550° C. indicates that fewer silicon-nitrogen and more boron-hydrogen bonds were formed with the film deposited at 550° C.

Silicon Oxide and Oxynitride Films

BTBAS also offers some process chemistry flexibility. For BTBAS based oxide processes, NH₃ can be substituted by an oxidizer such as N₂O.

To manufacture a silicon oxide nitride film, BTBAS may be used with NH₃ and an oxidizer such as N₂O. Additionally, disilane may be used with N₂O at temperatures as low as 500° C. The disilane and N₂O precursor film has a deposition rate of greater than 200 Å/min and a uniformity of less than 2 percent variability.

For each of the different films described above, a combination of approaches may be utilized for obtaining a film with optimum properties. That is, applying heat to some, but not all of the chamber surfaces in combination with using no dopant or one or more of the dopant-containing precursor gases may provide a film with the lowest dielectric constant and chamber surfaces with the least particle formation.

While the foregoing is directed to embodiments of the present invention, other and further embodiments of the invention may be devised without departing from the basic scope thereof, and the scope thereof is determined by the claims that follow.

1. A method for depositing a layer comprising silicon and nitrogen on a substrate, comprising:
vaporizing a silicon containing compound;
flowing the silicon containing compound into a mixing region of a processing chamber wherein the mixing region is defined by a heated adapter ring and at least one blocker plate;
flowing the silicon containing compound through a gas distribution plate into a processing region defined by heated walls, a substrate support, and the gas distribution plate; and then
exhausting residual gases through a heated exhaust system.

2. The method of claim 1, further comprising depositing the layer comprising silicon and nitrogen at a substrate support temperature from about 475° C. to about 800° C.

3. The method of claim 1, wherein the processing region of the chamber is at a pressure of about 10 to about 350 Torr during deposition.

4. The method of claim 1, wherein the processing region of the chamber is at a pressure of about 100 to about 700 mTorr.

5. The method of claim 1, wherein a portion of the exhaust system is heated to about 50° C. to about 160° C.

6. The method of claim 1, wherein the silicon containing precursor is combined with ammonia before entering the mixing region.

7. The method of claim 1, wherein the silicon containing precursor is selected from the group consisting of dichlorosilane, hexachlorodisilane, bis(tertiary butylamino)silane, silane, and disilane.

8. The method of claim 1, further comprising flowing a nitrogen containing compound into the mixing region wherein the nitrogen containing compound is selected from the group consisting of ammonia and hydrazine.

9. The method of claim 1, further comprising flowing a diluent gas into the mixing region wherein the diluent gas is selected from the group consisting of nitrogen, hydrogen, helium, and argon.

10. The method of claim 1, further comprising flowing a germanium containing compound into the mixing region, wherein the germanium containing compound is selected from the group consisting of germane and digermane.

11. The method of claim 1, further comprising flowing at least one dopant into the mixing region, wherein the at least one dopant is selected from the group consisting of a carbon containing compound and a boron containing compound.

12. The method of claim 11, wherein the carbon containing compound is bistertiary butylaminosilane.

13. The method of claim 11, wherein the boron containing compound is selected from the group consisting of borane, diborane, and boron trichloride.

14. A method for depositing at least one layer comprising silicon and nitrogen on a substrate, comprising:
flowing a silicon containing compound into a processing chamber having a mixing region defined by an adapter ring and at least one blocker plate;
heating the adapter ring and a portion of the exhaust system;
flowing a boron containing compound into the processing chamber; and
flowing a nitrogen containing compound into the processing chamber.

15. The method of claim 14, wherein the silicon containing compound is flowed into the processing chamber with a carbon containing compound.

16. The method of claim 14, wherein the carbon containing compound is bistertiary butylaminosilane.

17. The method of claim 14, wherein the boron containing compound is selected from the group consisting of borane, diborane, and boron trichloride.

18. The method of claim 14, wherein the silicon containing compound is selected from the group consisting of dichlorosilane, hexachlorodisilane, bistertiary butylaminosilane, silane, and disilane.

19. The method of claim 14, further comprising depositing a boron nitrogen hydrogen film.

20. The method of claim 19, further comprising depositing an additional silicon nitride film.
